(19) United States
(12) Patent Application Publication
(10) Pub. No.: US 2011/0305835 A1
(43) Pub. Date: Dec. 15, 2011

(54) SYSTEMS AND METHODS FOR A GAS TREATMENT OF A NUMBER OF SUBSTRATES

(75) Inventors: Ronald Thomas Bertram, JR., Mesa, AZ (US); Chantal Arena, Mesa, AZ (US); Ed Lindow, Scottsdale, AZ (US)

(73) Assignee: S.O.I.TEC SILICON ON INSULATOR TECHNOLOGIES, Bernin (FR)

(21) Appl. No.: 12/814,936

(22) Filed: Jun. 14, 2010

(51) Int. Cl. C23C 16/458; C23C 16/44; C23C 16/00

(52) U.S. Cl. 427/255.23; 118/730; 427/248.1; 427/255.5

(57) ABSTRACT

Systems and methods for the gas treatment of one or more substrates include at least two gas injectors in a reaction chamber, one of which may be movable. The systems may also include a substrate support structure for holding one or more substrates disposed within the reaction chamber. The movable gas injector may be disposed between the substrate support structure and another gas injector. The gas injectors may be configured to discharge different process gasses therefrom. The substrate support structure may be rotatable around an axis of rotation.

### FIELD

The various embodiments of the present invention generally relate to systems and methods for a gas treatment of a number of substrates within a reaction chamber and, more particularly, for systems and methods for a gas treatment for the deposition of materials upon a number of substrates within a reaction chamber.

### BACKGROUND

Systems for a gas treatment of a number of substrates, and, particularly, for gas treatment for the deposition of materials upon a number of substrates, have been extensively utilized for the formation of a number of material types including, for example, semiconductors, dielectrics, and ceramics. A number of systems may be utilized for the deposition of materials including, for example, systems utilizing technologies such as, metalorganic chemical vapor deposition (MOCVD), halide vapor phase epitaxy (HVPE), molecular beam epitaxy (MBE) and atomic layer deposition (ALD).

MOCVD systems (alternatively commonly referred to as organometallic vapor phase epitaxy (OMVPE), and metalorganic vapor phase epitaxy (MOVPE)) may be utilized for the formation of a number of materials including semiconductor materials (e.g., III-arsenides, III-phosphides, III-antimonides, III-nitride and mixtures thereof), dielectric materials (e.g., silicon nitride, silicon oxides) and ceramic materials (e.g., titanium nitrides, titanium oxides).

MOCVD systems commonly employ a number of process gases including, for example, one or more precursor gases for participation in chemical reactions over heated substrates for the formation of desired materials on the heated substrates. In addition, the process gases may include a number of additional gases; such additional gases may be utilized as, for example, carrier gases, dopants and dilutants.

As mentioned above, MOCVD may be utilized for the growth of semiconductor materials. In particular, MOCVD may be utilized for the growth of compound semiconductor materials. For example, MOCVD systems may be utilized for the formation of III-V type semiconductor materials, wherein the process gases may include one or more group III precursors (e.g., metal alkyls), one or more group V precursors (e.g., arsine, phosphine, ammonia and hydrazine) and a number of additional gases which may function, for example, as carrier gases, dopants and dilutants (e.g., hydrogen, helium, argon, silane and bis(cyclopentadienyl)magnesium). The process gases are commonly introduced into the reaction chamber of the MOCVD system utilizing a number of gas injectors. The gas injectors are configured to promote interaction of the process gases over a heated substrate, such that a material is deposited upon the heated substrate.

The actual and relative positions of the numerous gas injectors within the reaction chamber may influence the quality of the deposited material. In addition, the actual and relative positions of the numerous gas injectors may also influence the cleanliness of the reaction chamber and the operation of various components within the reaction chamber.

### BRIEF SUMMARY

The various embodiments of the present invention generally relate to systems and methods for the gas treatment of one or more substrates within a reaction chamber, and, more particularly, to systems and methods for the deposition of one or more materials upon at least one substrate within a reaction chamber. The systems and methods are now briefly described in terms of example embodiments of the invention. This summary is provided to introduce a selection of concepts in a simplified form that are further described in the detailed description of the example embodiments of the invention. This summary is not intended to identify key features or essential features of the claimed subject matter, nor is it intended to be used to limit the scope of the claimed subject matter.

In some embodiments, the present invention includes a system for the gas treatment of at least one substrate. The system may include a reaction chamber and at least one substrate support structure configured to hold at least one substrate disposed within the reaction chamber. The substrate support structure may be rotatable around an axis of rotation of the at least one substrate support structure. The system may also include a plurality of gas injectors. For example, the system may including at least one static gas injector and at least one mobile gas injector. The static gas injector may be disposed over the substrate support structure within the reaction chamber. The mobile gas injector also may be disposed over the substrate support structure. The mobile gas injector may be movable toward and away from the substrate support structure, and may include a drive for moving the mobile gas injector toward and away from the substrate support structure, and one or more gas outlet ports for discharging one or more process gasses from the mobile gas injector.

In additional embodiments, the present invention includes a gas treatment system that includes at least one substrate support structure configured to hold at least one substrate within a reaction chamber, a first gas injector separated from the support structure, and a second gas injector comprising at least one gas outlet port that is disposed between the first gas injector and the substrate support structure. The second gas injector may be movable between a first position and a second position within the reaction chamber. The at least one gas outlet port of the second gas injector may be located closer to the at least one substrate support structure when the second gas injector is in the second position relative to when the second gas injector is in the first position.

Additional embodiments of the invention include a method for the gas treatment of at least one substrate within a reaction chamber. At least one gas outlet port of at least one mobile gas injector may be positioned at a first location within the reaction chamber. Such positioning of the at least one gas outlet port may include decreasing a first separation distance between the at least one gas outlet port of the mobile gas injector and at least one static gas injector, and increasing a second separation distance between the at least one gas outlet port of the mobile gas injector and a substrate support structure within the reaction chamber. At least one substrate may be loaded upon the substrate support structure, and the at least one gas outlet port of the at least one mobile gas injector may be moved from the first location to a second location within the reaction chamber. Such moving of the at least one gas outlet port may include increasing the first separation distance between the at least one gas outlet port of the at least one mobile as injector and the at least one static gas injector, and decreasing the second separation distance between the at least one gas outlet port of the at least one mobile gas injector and the substrate support structure. At least one process gas may be discharged from the at least one mobile gas injector, and at least another, different process gas may be discharged from the at least one static gas injector.

### BRIEF DESCRIPTION OF THE DRAWINGS

The present invention may be understood more fully by reference to the following detailed description of example embodiments of the present invention, which are illustrated in the appended figures in which:

FIG. 1 schematically illustrates a general overview of a non-limiting example system for the gas treatment of a number of substrates and, particularly, for the deposition of materials upon a number of substrates.

FIGS. 2A and 2B schematically illustrate example embodiments of systems and methods including a static gas injector and a mobile gas injector.

FIGS. 3A and 3B schematically illustrate expanded views of non-limiting example drive systems for a mobile gas injector.

FIGS. 4A and 4B schematically illustrate expanded cross-sectional views of non-limiting gas outlet port configurations of a mobile gas injector and a static gas injector.

### DETAILED DESCRIPTION

The illustrations presented herein are not meant to be actual views of any particular structure, material, apparatus, system, or method, but are merely idealized representations that are employed to describe the present invention.

Headings are used herein for clarity only and without any limitation. A number of references are cited herein, the disclosures of which are incorporated herein, in their entirety, by this reference for all purposes. Further, none of the cited references, regardless of how characterized herein, is admitted as prior art relative to the present invention.

As used herein, the term “reaction chamber” means and includes any type of enclosure in which one or more gases are used to treat one or more substrates.

As used herein, the term “substrate” means and includes any structure that has been, or will be, treated using one or more gases in a reaction chamber.

As used herein, the term “substrate support structure” means and includes any device that is used to support one or more substrates within a reaction chamber. Substrate support structures include, but are not limited to, susceptors that support substrates across entire bottom surfaces of the substrates, ring-shaped structures that support substrates only along peripheral edges of the substrates, and tripod-like structures that support substrates at three or more points on the bottoms of the substrates.

As used herein, the term “gas injector” means and includes any device or apparatus used to inject gas within a reaction chamber.

As used herein, the term “gas outlet port” means and includes the outlet of a gas injector from which gas exits the gas injector and enters a space within a reaction chamber.

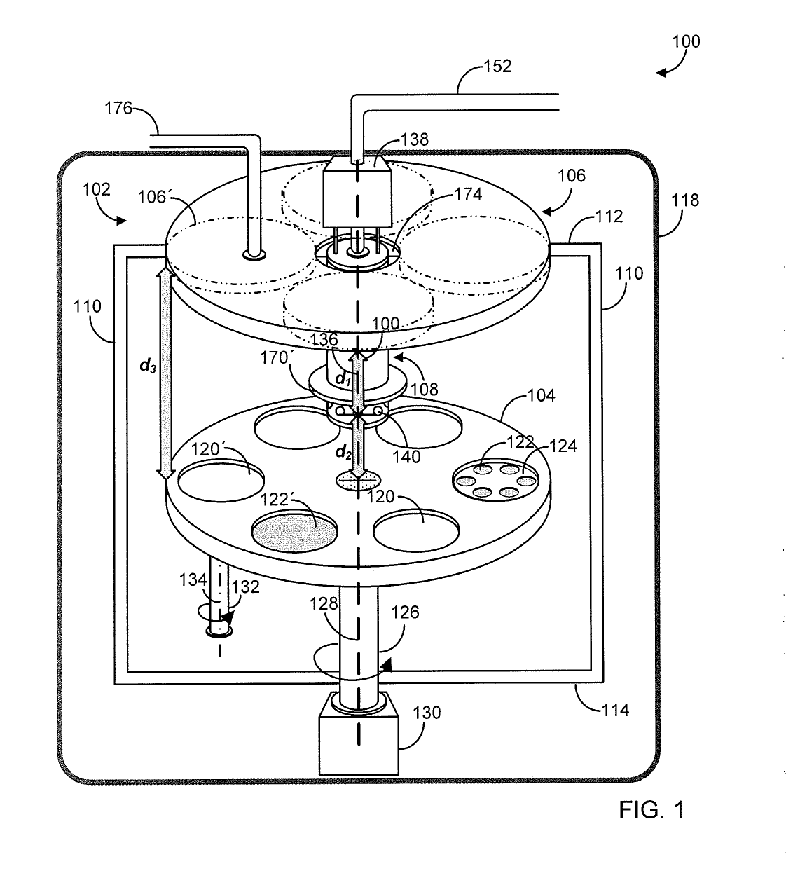

Example embodiments of the present invention comprise systems and methods for the gas treatment of a number of substrates (e.g., for the deposition of materials upon a number of substrates), and, more particularly, to systems and methods for the chemical vapor deposition of materials on a number of substrates. Embodiments of the invention may include, for example, utilizing a number of gas injectors within a reactor chamber, wherein the gas injectors may include one or more static gas injectors and one or more mobile gas injectors. The one or more mobile gas injectors may be moved relative to the one or more static gas injectors, as well as to the number of substrates carried upon a substrate support structure. Such gas injectors may assist in improving the quality of the deposited material or materials, and may improve the cleanliness of the reaction chamber or components of the reaction chamber. As a result, the usable lifetime of the reaction chamber or one or more components of the reaction chamber may be lengthened. Example embodiments of systems of the invention are described below with reference to FIG. 1. FIG. 1 illustrates a general overview of a non-limiting example system 100 for the gas treatment of a number of substrates, and particularly for the deposition of materials upon a number of substrates. The system 100 includes a reaction chamber 102, a substrate support structure 104, a static gas injector 106 and a mobile gas injector 108. The reaction chamber 102 may include a number of sidewalls 110, a ceiling 112 and a floor 114, and may be surrounded by reactor housing 118.

The materials employed in fabricating reaction chamber 102 may be selected to be compatible with the corrosive chemistries, temperatures and pressures commonly employed during deposition processes. Such materials may include, for example, quartz and stainless steels.

Reaction chamber 102 may include a substrate support structure 104 comprising a number of disc-shaped depressions, commonly referred to as pockets 120. Each pocket 120 may be configured to receive a substrate 122 or substrate carrier 124 therein, such that the substrate support structure 104 may carry a number of substrates 122 or substrate carriers 124. The non-limiting example illustrated in FIG. 1 depicts a disc-shaped substrate support structure 104 that includes six separate pockets 120 for carrying substrates 120 and/or substrate carriers 124. The substrate support structure 124 may have any of a number of other configurations, and may have any number of pockets 120. Furthermore, the pockets 120 may be located at other positions than those of the embodiment illustrated in FIG. 1. For example, each pocket 120 may include a single substrate 122′, or a substrate carrier 124 capable of carrying a plurality of substrates 122. Thus, each substrate support structure 104 may carry a plurality of substrates 122, and may carry substrates 122 of differing diameters (e.g., 2″, 4″, 6″, 8″ or 12″) during a single deposition process.

Substrate support structure 104 may be heated by one or more heating elements. For example, one or more of resistive heating elements, lamp based heating elements, inductive heating elements, and radio frequency heating elements (not shown) may be used for raising the temperature of the substrates 122 carried by the substrate support structure 104 to a temperature desirable for a deposition process. The system 100 may also include a supporting spindle 126 upon which the substrate support structure 104 may be mounted. The supporting spindle 126 may be configured to rotate within the reaction chamber 102 about an axis of rotation 128, such that the substrate support structure 104 mounted to supporting spindle 126 also may rotate about axis of rotation 128. Movement of the substrates 122 within the reaction chamber 102 by rotation of the substrate support structure 104 about the axis of rotation 128 during a deposition process may be utilized to counteract growth inhomogeneities and may improve the uniformity of the deposited materials. Supporting spindle 126 may be rotated by drive 130. Drive 130 may comprise, for example, a motor. In some embodiments, the supporting spindle 126 may be magnetically coupled to the drive 130 to supporting spindle 126 though reaction chamber 102. The speed of rotation about the axis of rotation 128 may be variable to allow for process adjustment (e.g., optimization).

In further embodiments of the invention, the individual pockets 120 may also be independently rotated such that the individual pockets 120 may be rotated independent of the rotation of the substrate support structure 104. For example, pocket 120′ may be connected to an additional drive system (not shown) through a spindle 132 by, for example, magnetic coupling. In such an embodiment, the pocket 120′ and the spindle 132 may be rotated about an additional axis of rotation 134 that may extends through a center of the pocket 120′. In additional embodiments, the pocket 120′ may be driven to rotate about the axis of rotation 134, utilizing a gearing system (not shown) coupling the spindle 132 to the supporting spindle 126, such that rotation of the supporting spindle 126 drives rotation of the spindle 132 through the gearing system. In yet further embodiments of the invention, the system 100 may not include the substrate support structure 104, and each of plurality of substrates 122 and/or substrate carriers 124 may be individually supported by separate supporting spindles like the spindle 132.

In some embodiments, the supporting spindle 126 may be magnetically coupled to the drive 130 for rotation purposes using techniques like those described in U.S. Pat. No. 5,795,448, which issued Aug. 18, 1998 to Hurwitt et al. and is incorporated herein by reference in its entirety.

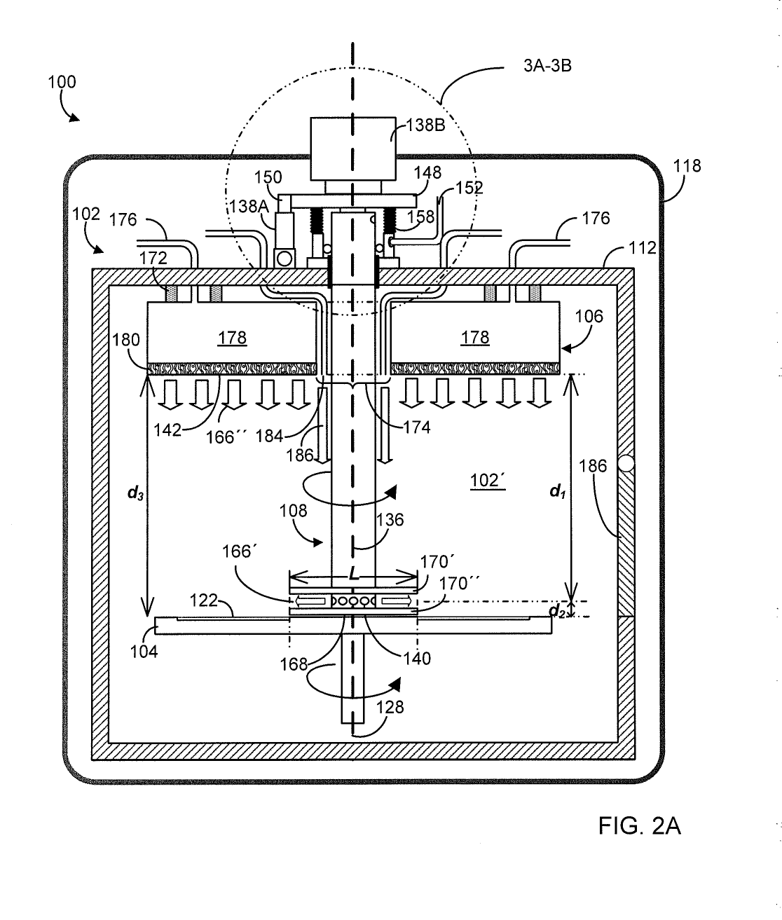

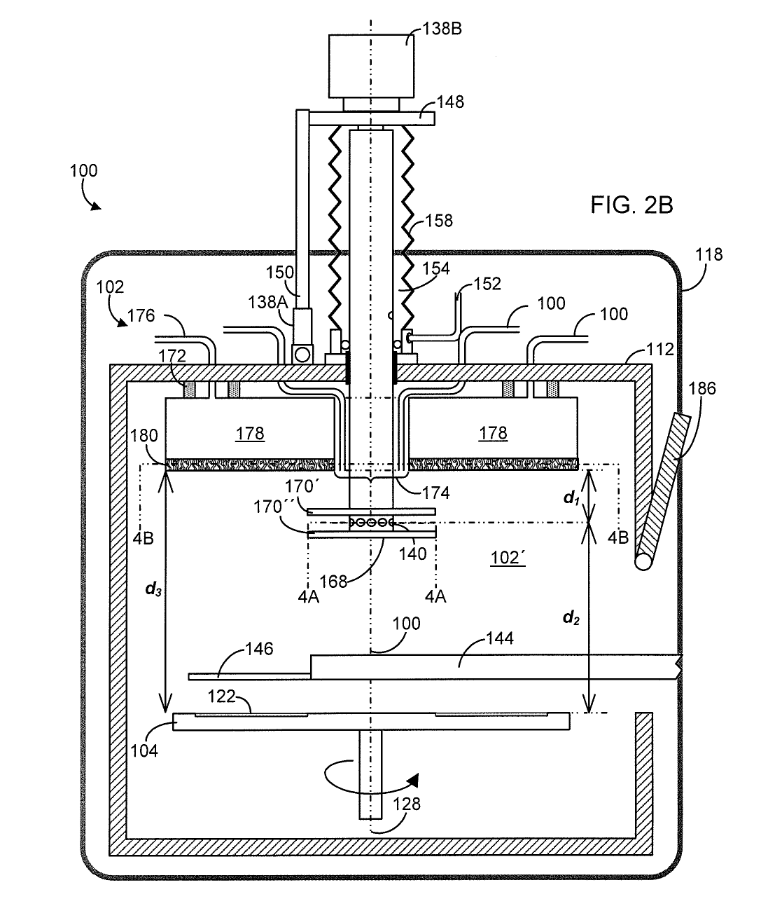

As previously mentioned, the reaction chamber 102 may include one or more mobile gas injectors. As shown in FIG. 1, the reaction chamber 102 includes a mobile gas injector 108. Additional details of the mobile gas injector 108 are described below with reference to FIGS. 2A and 2B, FIGS. 3A and 3B and FIG. 4A.

With continued reference to FIG. 1, the mobile gas injector 108 may comprise a generally cylindrical structure. In additional embodiments, the mobile gas injector 108 may have another shape or configuration. The mobile gas injector 108 may be fabricated from any of a number of materials, and may be fabricated from materials that are compatible with the corrosive chemistries, temperatures and pressures to which the materials may be subjected during deposition processes. As non-limiting examples, such materials may include quartz and stainless steels.

The mobile gas injector 108 may be disposed within the reaction chamber 102 over the substrate support structure 104 and the substrates 122 carried by the substrate support structure 104. The mobile gas injector 108 may have a central axis 136 coincident with axis of rotation 128 of the substrate support structure 104. The mobile gas injector 108 may also include one or more drives 138 for providing one or more components of motion (i.e., degrees of freedom in movement) such that the mobile gas injector 108 and one or more gas outlet ports 140 associated with mobile gas injector 108 may move relative to one or more static gas injectors 106 and relative to the substrate support structure 104. For example, the drive 138 may be used to provide a component of motion along the axis of rotation 128 (i.e., in the vertically up and down directions from the perspective of the figures).

In greater detail, the ability to move the mobile gas injector 108 along the axis of rotation 128 may be advantageous for a number of reasons. For example, referring to FIG. 2A, a first separation distance d₁ may be defined as the distance between the location of the one or more gas outlet ports 140 of the mobile gas injector 108 and the location of a plurality of gas outlet ports 142 of the static gas injector 106 along the axis of rotation 128. By selectively controlling movement of the mobile gas injector 108 along the axis of rotation 128 in the vertically upward and downward directions (from the perspective of the figures), the first separation distance d₁ may be selectively controlled (i.e., increased or decreased) as desired.

In addition, a second separation distance d₂ may be defined as the distance between the location of the one or more gas outlet ports 140 of the mobile gas injector 108 and the location of the substrate support structure 104 along the axis of rotation 128. By selectively controlling movement of the mobile gas injector 108 along the axis of rotation 128 in the vertically upward and downward directions (from the perspective of the figures), the second separation distance d₂ also may be selectively controlled (i.e., increased or decreased) as desired. In some embodiments, the first separation distance d₁ and the second separation distance d₂ may be inversely proportional, and may not be varied independently of one another. In other embodiments, however, it may be possible to vary the first separation distance d₁ and the second separation distance d₂ independently of one another, and it may be possible to change one without changing the other. For example, the substrate support structure 104 could be configured to allow the substrate support structure 104 to move with the mobile gas injector 108.

In some embodiments of methods of the invention, it may be advantageous to position the mobile gas injector 108 and the one or more gas outlet ports 140 thereof proximate to the substrate support structure 104. For example, the mobile gas injector 108 may be positioned within the reaction chamber 102 such that the first separation distance d₁ is relatively large (e.g., maximized) and the second separation distance d₂ is relatively small (e.g., minimized), as illustrated in FIG. 2A. For example, during deposition processes, it may be advantageous to position the one or more gas outlet ports 140 of the mobile gas injector 108 proximate to the substrate support structure 104, such that precursor gas may be injected from the one or more gas outlet ports 140 proximate to the one or more substrates 122 carried by the substrate support structure 104. As a non-limiting example, it may be advantageous to position the one or more gas outlet ports 140 of the mobile gas injector 108 at a distance between about one millimeter (1 mm) and about one hundred and fifty millimeters (150 mm) from the substrate support structure 104 during deposition processes.

In addition, during deposition processes, it may be advantageous to maintain a significant separation between the one or gas outlet ports 140 of the mobile gas injector 108 and the plurality of gas outlet ports 142 of the one or more static gas injectors 106, as shown in FIG. 2A. As a non-limiting example, it may be advantageous to maintain a separation between the one or gas outlet ports 140 of the mobile gas injector 108 and the plurality of gas outlet ports 142 of the one or more static gas injectors 106 of between about fifty millimeters (50 mm) and about five hundred millimeters (500 mm) during deposition processes. Maintaining a significant separation between the positions of gas outlet ports 140 and 142 may be utilized to prevent premature mixing of the precursor gases dispensed respectively therefrom, as such premature mixing of the precursor gases may lead to undesirable gas phase interactions.

In additional embodiments of methods of the invention, it may be advantageous to position the mobile gas injector 108 and the gas outlet ports 140 thereof proximate to the static gas injector 106. In other words, the mobile gas injector 108 may be positioned within reaction chamber 102 such that the first separation distance d₁ is relatively small (e.g., minimized) and the second separation distance d₂ is relatively large (e.g., maximized), as shown in FIG. 2B. For example, during loading of substrates 122 into the reaction chamber 102 and/or removal of substrates out from the reaction chamber 102, it may be advantageous to decrease the first separation distance d₁ in order to provide physical clearance space within reaction chamber 102. The substrates 122 may be manually or robotically loaded into the reaction chamber 102 and/or unloaded from the reaction chamber 102. For example, as shown in FIG. 2B, a robotic arm 144 with a suitable substrate pick-up system 146 (e.g., a Bernoulli wand apparatus) thereon may be used to robotically move substrates into and out from the reaction chamber 102. Decreasing the first separation distance d₁ may prevent the mobile gas injector 108 from interfering mechanically with the robotic arm 144, body of a human operator, and/or with the substrates 122.

In some embodiments of methods of the invention, the mobile gas injector 108 and the gas outlet ports 140 thereof may be positioned at an intermediate location such that the first separation distance d₁ and the second separation distance d₂ are located intermediately between maximum and minimum values. As a non-limiting example, each of the first separation distance d₁ and the second separation distance d₂ may be between about one millimeter (1 mm) and about five hundred millimeters (500 mm). During deposition processes, the position of the mobile gas injector 108 and the one or more gas outlet ports 140 thereof may be utilized as a tuning parameter for forming a desirable material on the substrates 122 carried by the substrate support structure 104. The mobile gas injector 108 and associated gas outlet ports 140 may be moved to a selected position prior to deposition. Furthermore, the mobile gas injector 108 and the gas outlet ports 140 may be moved during a deposition process to adjust the deposition process as desirable (e.g., to improve or optimize one or more aspects of the deposition process).

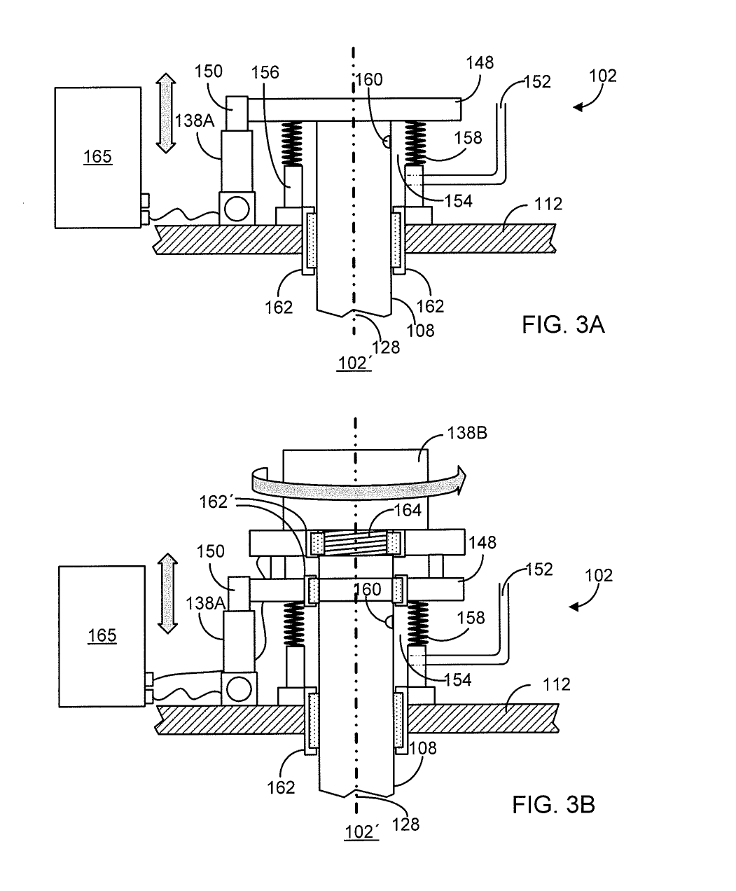

A number of methods may be utilized to provide components of motion to the mobile injector 108. FIGS. 3A and 3B are enlarged schematic views of the upper portion of the reaction chamber 102 and the mobile gas injector 108, and illustrate non-limiting examples of means for providing components of motion to the mobile gas injector 108.

Referring to FIG. 3A, a component of motion along the axis of rotation 128 may be provided to the mobile gas injector 108 by the drive 138A. The drive 138A may comprise a linear drive and may be actuated by one or more of hydraulic, pneumatic, electrical and mechanical power. Drive 138A may be connected to a drive plate 148 through a drive shaft 150. The drive plate 148 may be connected to the mobile gas injector 108 such that actuation of the drive 138A results in motion of the mobile gas injector 108 along the axis of rotation 128 (i.e., in the vertically upward and downward directions from the perspective of the figures).

A process gas inlet port 152 may be utilized to supply process gas into the reaction chamber 102 through the mobile gas injector 108. In some embodiments, process gas introduced into the reaction chamber 102 through the mobile gas injector 108 may include, for example, metalorganic precursors (e.g., trimethylaluminum, triethylaluminum, trimethylgallium, triethylgallium, trimethylindium, triethylindium, etc.), dopant gases and dilutant gases.

Process gas introduced through the gas inlet port 152 may enter an antechamber 154. The antechamber 154 may be enclosed and defined by, for example, the drive plate 148, housing elements 156 and flexible bellows 158, as shown in FIGS. 3A and 3B. The antechamber 154 may be in fluid connection with the mobile gas injector 108 through an inlet 160, such that process gas introduced by way of the gas inlet port 152 may be transported to the mobile gas injector 108 and out through the outlet ports 140 of the mobile gas injector 108. Antechamber 154 may be fluidically sealed from the reaction chamber interior 102′ by seals 162. The seals 162 may comprise, for example, o-rings or ferrofluidic seals. The seals 162 may provide isolation of the antechamber 154, but may also allow movement of the mobile gas injector 108 through the reaction chamber ceiling 112.

Upon actuation of the drive 138A, the flexible bellows 158 may expand and the volume of the antechamber 154 may increase accordingly (see FIG. 2B) while maintaining a fluid connection between the gas inlet port 152 of the mobile gas injector 108 and the inlet 160. The flexible bellows 158 may be fabricated from any of a number of materials such as, for example, a metal, a polymer, or any other suitable flexible material.

In addition to providing motion along the axis of rotation 128, the mobile gas injector 108 may also be rotatable about the axis of rotation 128, as indicated by the directional arrow in FIG. 3B. Rotation of the mobile gas injector 108 about the axis of rotation 128 may be provided by a drive 138B. The drive 138B may comprise a rotational drive, and may be actuated by one or more of hydraulic, pneumatic, electrical and mechanical power. The drive 138B may be connected to the mobile gas injector 108 through a drive shaft 164. The drive shaft 164 may be connected to the mobile gas injector 108 such that actuation of the drive 138B results in rotational motion of the mobile gas injector 108 around the axis of rotation 128. Additional seals 162′ may be provided to ensure substantially friction free movement of the mobile gas injector 108 while maintaining a fluidic seal of the antechamber 154. In some embodiments, it may be advantageous to rotate the mobile gas injector 108 during a deposition process. For example, rotation of the mobile gas injector 108 may increase uniformity of deposited materials on the substrates 122.

The one or more drives connected to the mobile gas injector 108 may be controlled by a number of methods. In some embodiments, the drive 138A and/or the drive 138B may be controlled using a control system 165 shown in FIGS. 3A and 3B. The control system 165 may be operatively coupled to the mobile gas injector 108, the reaction chamber 102 and one or more drives 138 in such a manner as to enable the control system 165 to control their operation. The control system 165 may comprise computer system software.

The control system 165 may include one or more input devices, which may be used to control the operation of the reaction chamber 102, and, particularly, the mobile gas injector 108. For example, a user may provide an indication of a desired mobile gas injector position and/or rotation speed within the reaction chamber 102 using the one or more input devices, and the control system 165 may control the operation of the mobile gas injector 108 and actuate the one or more drives 138 to move the mobile gas injector 108 to a desired position at a desired speed. Further, a user may provide an indication of a desired growth parameter of process gas in reaction chamber 102 using one or more input devices, and the control system 165 may control the position and rotation of the mobile gas injector 108 within reaction chamber 102 to drive the growth parameter toward a desired value thereof. Such operation of the mobile gas injector 108 may utilize a closed-loop control system. In other words, one or more in situ monitoring devices or systems (e.g., sensors) (not shown) may be used to monitor the status of the deposited material and to provide feedback data to the control system 165, and the control system 165 control the position and/or the rotation speed of the mobile gas injector 108 responsive to the feedback data received from such monitoring devices or systems during a deposition process.

As illustrated in FIG. 2A, the mobile gas injector 108 may include one or more gas outlet ports 140. The size, shape, position and/or grouping of the gas outlet ports 140 of the mobile gas injector 108 may be configured to provide a desired distribution of process gases 166″ across the substrates 122. The spatial density of gas outlet ports 140 may be selected in view of characteristics of gas flow from the gas outlet ports 140 to substrate support structure 104 and the associated substrates 122 carried thereon. Such characteristics may include the gas footprint, or coverage area, produced by the gas outlet ports 140 on the number of substrates 122. Selection of particular parameters for the arrangement of the gas outlet ports 140 may be made from knowledge of the gas flow characteristics, and estimated parameters can be refined by experimentation. In some embodiments, a uniform distribution of one or more process gases across the substrates 122 may be desired, in which case, gas outlet ports 140 may be evenly distributed around the circumference of the mobile gas injector 108.

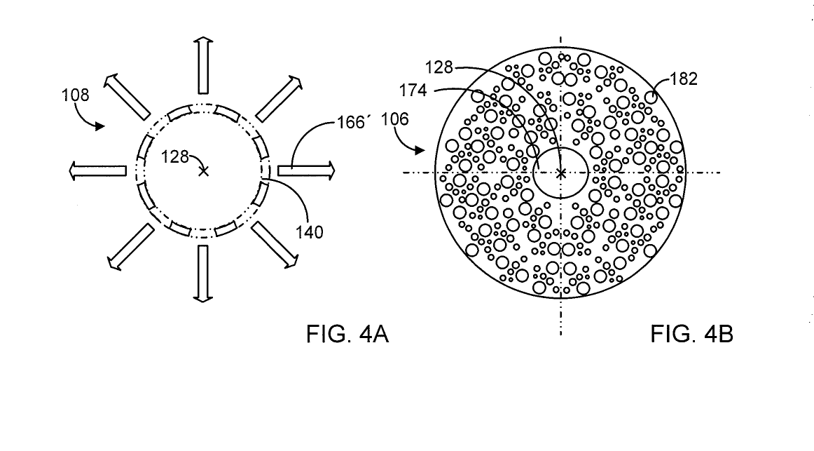

Such a configuration of gas outlet ports 140 is illustrated in the non-limiting example shown in FIG. 4A. FIG. 4A illustrates a schematic, cut-away view of the mobile gas injector 108 and illustrates eight (8) gas outlet ports 140 that are evenly distributed around the circumference of the mobile gas injector 108. The gas outlet ports 140 produce corresponding radial gas streams of process gases 166′, which are discharged across the substrates 122 from the mobile gas injector 108 in a direction that is oriented at an angle greater than zero (e.g., at least substantially perpendicular) to the axis of rotation 128. In other words, gas may be discharged out from the gas outlet ports 140 in a direction that is oriented at about 90° to the axis of rotation 128. It should be noted also that, although FIG. 1 and FIGS. 2A and 2B illustrate the gas outlet ports 140 as having a circular shape, other shapes may be utilized in additional embodiments of the invention.

In some embodiments of the systems of the invention, the one or more gas outlet ports 140 of the mobile gas injector 108 may be positioned proximate to the base region 168 of the mobile gas injector 108, as shown schematically in FIG. 2A. The proximity of the one or more gas outlet ports 140 to the base region 168 may contribute to reducing (e.g., minimizing) the second separation distance d₂ between the gas outlet ports 140 and the substrate carrier structure 104. Positioning the gas outlet ports 140 in such a manner as to reduce or minimize the second separation distance d₂ may be desirable during some deposition processes, as the radial gas streams 166′ discharged from the gas outlet ports 140 may be spatially separated from process gases 166″ discharged from the static gas injector 106 until the gases interact over and proximate to the substrates 122, thereby reducing (e.g., preventing) unwanted gas phase interactions and problems associated with such gas phase interactions.

In further embodiments of systems of the invention, one or more deflector plates, such as a first deflector plate 170′ and/or a second deflector plate 170″, may be employed in conjunction with the mobile gas injector 108, as illustrated in FIGS. 2A and 2B. The deflector plates 170′, 170″ may be integral parts or features of the mobile gas injector 108. In other embodiments, the deflector plates 170′, 170″ may comprise separate members that are attached to and carried by the mobile gas injector 108. The shape, position and size of deflector plates 170′, 170″ may be selected to aid in directing the one or more radial gas streams 166′ in the intended discharge directions, such that the radial gas streams 166′ are discharged in a direction oriented at an angle greater than zero (e.g., at least substantially perpendicular) to the axis of rotation 128.

The first deflector plate 170′ may be disposed proximate (e.g., adjacent) the one or more gas outlet ports 140 associated with the mobile gas injector 108 on a side thereof remote from the substrate support structure 104. In some embodiments of the invention, the second deflector plate 170″ may be disposed proximate (e.g., adjacent) the gas outlet ports 140 associated with the mobile gas injector 108 on a side thereof proximate the substrate support structure 104. The second deflector plate 170″ may be included, for example, in embodiments in which the substrate support structure 104 includes a number of spindles, as illustrated in FIG. 1.

The deflector plates 170′, 170″ may be sized such that the deflector plates 170′, 170″ shield the radial gas streams 166′ discharged from the gas outlet ports 140 of the mobile gas injector 108 until the gas of the radial gas streams 166′ is located in the vicinity of the substrates 122 carried by substrate carrier structure 104. As illustrated in FIG. 2A, the deflector plates 170′, 170″ have an outer diameter L and extend over the substrate support structure 104 up to the outer edges of the substrates 122. Such a configuration of the deflector plates 170′, 170″ may be desirable as process gas of the radial gas streams 166′ may remain substantially separated from the process gas 166″ discharged from the one or more static gas injectors 106 until the process gases are located above and proximate (e.g., adjacent) the substrates 122.

The systems of some embodiments of the invention may also include one or more static gas injectors 106. Non-limiting examples of static gas injectors are illustrated in FIG. 1, FIGS. 2A and 2B and FIG. 4B. The reaction chamber 102 may include a number of static gas injectors. For example, FIG. 1 illustrates a solid single static gas injector 106. In additional embodiments, the reaction chamber 102 may include a plurality of static gas injectors, such as the four static gas injectors 106′ shown in phantom, which may operate in conjunction with the mobile gas injector 108 for the gas treatment of the substrates 122.

In some embodiments of systems of the invention, the static gas injector 106 may be disposed vertically over the substrate support structure 104 (from the perspective of the figures) and may extend over the substrate support structure 104, as illustrated in FIG. 1 and FIGS. 2A and 2B. In greater detail, the static gas injector 106 may be sized and configured such that the static gas injector 106 may be capable of supplying a number of process gases to the substrates 122 within the reaction chamber 102. The static gas injector 106 may extend laterally, partially, or entirely, across the substrate support structure 104, such that the substrates 122 supported by the substrate support structure 104 may be gas treated by a single static gas injector 106.

The static gas injector 106 may be configured to be mounted to the reactor chamber 102, and the static gas injector 106 may be mounted at a preset separation distance d₃ from the substrate support structure 104. For example, a number of housing fixtures 172 (FIGS. 2A and 2B) may be utilized to affix the static gas injector 106 to the ceiling 112 of the reaction chamber 102, such that the static gas injector 106 is fixed at the preset separation distance d₃ from the substrates 122. In some embodiments of the invention, the preset separation distance d₃ may be selected such that there may be sufficient separation between the static gas injector 106 and the number of heated substrates 122, such that thermal energy generated from the heated substrates 122 may be prevented from heating the static gas injector 106 in any significant manner that might detrimentally affect the deposition process. In some embodiments, the preset separation distance d₃ may be between about fifty millimeters (50 mm) and about five hundred millimeters (500 mm). Preventing significant heating of the static gas injector 106 may limit the formation of undesirable deposits upon the static gas injector 106, thereby limiting the need to perform time-consuming cleaning processes upon the static gas injector 106.

The static gas injector 106 may further be prevented from unwanted heating by the addition of circulating water-cooling systems (not shown). Such circulating water cooling systems are known in the art and may be utilized in embodiments of the present invention to assist in avoiding the formation of undesirable deposits upon the static gas injector 106.

The static gas injector 106 may also include an aperture 174 formed therein, as shown in FIG. 1 and FIGS. 2A and 2B. The aperture 174 may have a central axis that is coincident with axis of rotation 128. The aperture 174 maybe sized and configured to receive the mobile gas injector 108 through the aperture 174, such that the central axis of aperture 174 is coincident with the central axis 136 of the mobile gas injector 108 in some embodiments of the invention.

The static gas injector 106 may be configured such that at least a portion of the mobile gas injector 108 is capable of passing through the static gas injector 106 along the axis of rotation 128. For example, it may be desirable for the central axis 136 of the mobile gas injector 108 to be coincident with the axis of rotation 128, such that the mobile gas injector 108 may move along the axis of rotation 128. Thus, the static gas injector 106 may include the aperture 174 to allow the mobile gas injector 108 to move within the reaction chamber 102. It should be noted that the aperture 174 may be sized and configured to allow a plurality of mobile gas injectors like the mobile gas injector 108 to pass through the aperture 174. In additional embodiments, the static gas injector 106 may comprise a plurality of apertures like the aperture 174, and each aperture of the plurality may be configured to allow one mobile gas injector of a plurality of gas injectors (like the mobile gas injector 108) to pass through the respective aperture.

The static gas injector 106 may also include one or more gas inlet ports 176 in fluid communication with an antechamber 178 (see FIGS. 2A and 2B). Thus, process gas may be supplied to the antechamber 178 from a source of the process gas through the one or more gas inlet ports 176.

In some embodiments, a porous gas permeable base plate 180 may be disposed at the base of the antechamber 178. Pores of the porous gas permeable base plate 180 may define a plurality of gas outlet ports 142 that are in fluid connection with the antechamber 178, such that a process gas 166″ may be discharged out from the antechamber 178 and into the reaction chamber 102 through the pores (which define the gas outlet ports 142) of the porous gas permeable base plate 180. The process gas 166″ may be discharged from the plurality of gas outlet ports 142 in a downward direction (from the perspective of the figures) toward the substrates 122.

In greater detail, the one or more gas inlet ports 176 in fluid connection with the antechamber 178 may be utilized for the introduction of a number of process gases to the reaction chamber interior 102′ through the static gas injector 106. In some embodiments of systems of the invention, process gas introduced into the reaction chamber interior 102′ through the static injector 106 may include, for example, group V precursors (e.g., arsine, phosphine, ammonia, dimethylhydrazine, etc.) as well as various carrier gases, dopant gases and dilutant gases.

The one or more gas inlet ports 176 may be utilized to feed the antechamber 178. As previously mentioned, the antechamber 178 may include a porous gas permeable base plate 180. The antechamber 178 may be capable of equalizing the pressure within the gas inlet ports 176 in such a manner as to provide an even distribution of process gas to the gas outlet ports 142 associated with the porous gas permeable base plate 180. The porous gas permeable base plate 180, commonly referred to as a frit, may be fabricated from, for example, a metal material or a ceramic material, and may contain a plurality of pores fluidly connecting the reaction chamber interior 102′ with the antechamber 178, therefore forming the plurality of gas outlet ports 142, as illustrated in more detail in the schematic cross-sectional view of FIG. 4B.

As illustrated in the schematic cross-sectional view of the static gas injection of FIG. 4B, the static gas injector 106 includes a plurality of pores 182 acting as a plurality gas outlet ports 142 for introducing process gas into the reaction chamber 102. FIG. 4B also illustrates that the static gas injector 106 may also include an aperture 174 as previously described herein, which may be disposed proximate to the axis of rotation 128. The static gas injector 106 may have a central axis that is coincident with the axis of rotation 128. As previously discussed, the aperture 174 may be sized and configured to receive at least a portion of the mobile gas injector 108 through the aperture 174.

As described above, the plurality of gas outlet ports 142 in fluid connection with the antechamber 178 by means of the porous gas permeable base 180 may cause the process gas 166″ to be discharged in a downward direction (from the perspective of the figures) toward the substrates 122 that is at least substantially parallel to the axis of rotation 128. However, in addition to providing a process gas source, the plurality of discharged gas streams 166″ may provide a gas curtain of protection to the plurality of gas outlet ports 142 associated with static gas injector 106, since the plurality of gas outlet ports 142 discharge a plurality of gas streams 166″ which may substantially prevent undesirable deposits from forming on static gas injector 106.

Some embodiments of systems of the invention may also include one or more additional gas outlet ports 184, as shown in FIG. 2A. Such additional gas outlet ports 184 may be disposed between the static gas injector 106 and the mobile gas injector 108. The one or more additional gas outlet ports 184 may provide one or more protective gas curtains 186. The one or more additional gas outlet ports 182 may be utilized to produce one or more protective gas curtains 186, which may protect the mobile gas injector 108 from buildup of undesirable deposits on the mobile gas injector 108, which may extend the time periods that may be allowed to pass between reaction chamber cleaning processes.

Embodiments of the invention may also include methods for the gas treatment of a plurality of substrates within a reaction chamber, and, particularly, to a gas treatment for the deposition of one or more materials on one or more substrates within a reaction chamber. For example, the methods may include forming one or more materials on one or more substrates using the systems described above. Such methods may be utilized for the formation of any of a number of materials including, for example, semiconductor materials (e.g., III-arsenides, III-phosphides, III-antimonides, III-nitride and mixtures thereof), dielectric materials (e.g., silicon nitride, silicon oxides, etc.) and ceramic materials (e.g., titanium nitrides, titanium oxides, etc.).

Embodiments of methods of the invention may include the use of a mobile gas injector 108, and may include positioning a mobile gas injector 108 within the range of positions of the mobile gas injector 108 relative to one or more static gas injectors 106 and relative to a substrate support structure 104, as previously described herein, in an effort to improve processes for the formation of desired material upon a one or more substrates 122.

Therefore, embodiments of methods of the invention may include positioning one or more gas outlet ports 140 associated with a mobile gas injector 108 along an axis of rotation 128 within the reaction chamber 102, as illustrated in, for example, FIG. 2B.

Positioning of the one or more gas outlet ports 140 associated with the mobile gas injector 108 may comprise decreasing a first separation distance d₁ between the one or more gas outlet ports 140 of the mobile gas injector 108 and the one or more gas outlet ports 142 of the one or more static gas injectors 106, and increasing a second separation distance d₂ between the one or more gas outlet ports 140 of the mobile gas injector 108 and a substrate support structure 104. Such a positioning of the one or more gas outlet ports 140 associated with the mobile gas injector 108 may place the gas outlet ports 140 proximate to the one or more static gas injectors 106 and leave a substantial separation between the base 168 (i.e., bottom surface) of the mobile gas injector 108 and the substrate support structures 104. Such a substantial separation between the base 168 of the mobile gas injector 108 and the substrate support structure 104 may be sufficient for the introduction of a loading and/or unloading mechanism 144 including a pickup mechanism 146 to be inserted into the interior of the reaction chamber 102′ for the input and/or retrieval of one or more substrates 122. As a non-limiting example, the second separation distance d₂ between the one or more gas outlet ports 140 of the mobile gas injector 108 and the substrate support structure 104 may be increased to between about twenty five millimeters (25 mm) and about five hundred millimeters (500 mm).

Decreasing the first separation distance d₁ between the one or more gas outlet ports 140 of the mobile gas injector 108 and the one or more gas outlet ports 142 of the one or more static gas injectors 106 may comprise actuating the drive 138A, such that the drive 138A raises the drive plate 148 using the drive shaft 150, as illustrated in FIG. 2B and FIG. 3A. Raising the drive plate 148 may further comprise increasing the volume within the antechamber 154, as the drive plate 148 may be connected to bellows 158, and as bellows 158 unfolds or expands, the volume of the antechamber 154 may increase to accommodate the movement of the mobile gas injector 108.

Embodiments of methods of the invention may also include loading one or more substrates 122 upon a substrate support structure 104 that is rotatable around an axis of rotation 128. Referring to FIG. 2B, once the one or more gas outlet ports 140 associated with the mobile gas injector 108 are positioned proximate to the one or more static gas injectors 106, there may be sufficient separation between the base 168 of the mobile gas injector 108 and the substrate support structure 104 to accommodate the introduction of the mechanism 144 for loading and/or unloading substrates 122 into the interior of the reaction chamber 102′.

Loading of substrates 122, or loading of substrate carriers each carrying a plurality of substrates 122, may proceed with the opening of a gate valve 186 to allow access to the interior of the reaction chamber 102′. Such a gate valve 186 may be connected to a load-lock system (not shown) to allow environmental control of the interior of the reaction chamber 102′. The mechanism 144 may then enter the interior of the reaction chamber 102′. The mechanism 144 may comprise one or more pickup systems configured to pick up a substrate 122. Such pickup systems may include, for example, a mechanic pickup system or a Bernoulli wand type gas pick system. The pickup system may include a pickup head 146 for the manipulating one or more substrates 122 or substrate carriers each carrying a plurality of substrates 122. A plurality of substrates 122 may be loaded upon substrate support structure 102 utilizing the mechanism 144. Upon loading of a number of substrates 122 into the interior of the reaction chamber 102′, the mechanism 144 may be withdrawn from the interior of the reaction chamber 102′, and the gate valve 186 may be closed.

Embodiments of methods of the invention may also comprise positioning of the one or more gas outlet ports 140 associated with the mobile gas injector 108 by increasing the first separation distance d₁ between the one or more gas outlet ports 140 of the mobile gas injector 108 and the one or more gas outlet ports 142 of the one or more static gas injectors 106, and decreasing a second separation distance d₂ between the one or more gas outlet ports 140 of the mobile gas injector 108 and a substrate support structure 104, as illustrated in FIG. 2A. Such a positioning of the one or more gas outlet ports 140 associated with the mobile gas injector 108 may place one or more gas outlet ports 140 of the mobile gas injector 108 proximate to (e.g., at least substantially adjacent) substrate support structure 104. As a non-limiting example, the second separation distance d₂ between the one or more gas outlet ports 140 of the mobile gas injector 108 and the substrate support structure 104 may be decreased to between about one millimeter (1 mm) and about one hundred and fifty millimeters (150 mm).

Positioning one or more gas outlet ports 140 associated with the mobile gas injector 108 may be desirable for deposition processes to promote separation of process gases as previously discussed herein.

Increasing the first separation distance dₗ between the one or more gas outlet ports 140 of the mobile gas injector 109 and the one or more gas outlet ports 142 of the one or more static gas injectors 106 may comprise actuating a drive 138A, such that the drive 138A lowers a drive plate 148 using the drive shaft 150, as shown in FIG. 3A. Lowering the drive plate 148 may further comprise decreasing a volume within the antechamber 154, as the drive plate 148 may be connected to bellows 158, and as the bellows 158 folds inward or contracts, the volume within the antechamber 154 may decrease to accommodate the movement of the mobile gas injector 108.

Methods of the invention may further comprise discharging a plurality of process gases 166′ and 166″ from at least one of the mobile gas injector 108 and the one or more static gas injectors 106.

Discharging a plurality of process gases 166′ and 166″ may comprise discharging one or more process gases 166′ from the mobile gas injector 108 through the one or more gas outlet ports 140. Discharging the one or more process gases 166′ from the mobile gas injector 108 may produce one or more radial gas streams 166′ that may be oriented in a direction at an angle greater than zero (e.g., at least substantially perpendicular) to the axis of rotation 128. The process gases discharged from the one or more gas outlet ports 140 associated with the mobile gas injector 108 may include, for example, metal alkyls, such as trimethylaluminum, triethylaluminum, trimethylgallium, triethylgallium, trimethylindium, triethylindium, as well as carrier gases, dopant gases and dilutant gases.

Radial gas streams 166′ discharged from the gas outlet ports 140 associated with the mobile gas injector 108 may be directed utilizing one or more deflector plates 170′, 170″. As discussed previously, such deflector plates 170′, 170″ may also assist in maintaining separation of the process gases 166′ introduced from the mobile gas injector 108 and the process gases 166″ introduced from the one or more static gas injectors 106 until the process gases are in the vicinity of the substrates 122.

The process of discharging the process gases 166′ from the mobile gas injector 108 through the one or more gas outlet ports 140 may further include rotating the mobile gas injector 108 about the axis of rotation 128, and/or rotating the substrate support structure 104 about the axis of rotation 128. The rotation of the mobile gas injector 108 and/or the substrate support structure 104 about the axis of rotation 128 may be utilized to counteract growth inhomogeneities, and may improve the uniformity of the deposited materials.

Rotating the mobile gas injector 108 about the axis of rotation 128 may comprise actuating the drive 138B, such that the drive 138B rotates the drive shaft 164, as indicated in FIG. 3. Rotating the substrate support structure 104 may comprise driving rotation of the supporting spindle 126 (FIG. 1), which rotation may be driven by the drive 130. The drive 130 may comprise, for example, a motor, which may be magnetically coupled to the spindle 126 through the reaction chamber 102. Furthermore, the speed of rotation about the axis of rotation 128 may be variable to enable adjustment of process parameters (e.g., for process optimization).

The process of discharging one or more process gases may further include discharging one or more process gases 166″ from the one or more static gas injectors 106 through the plurality of gas outlet ports 142 that are in fluid communication with the antechamber 178 through the porous gas permeable base plate 180.

In greater detail, the one or more static gas injectors 106 may be utilized for introducing one or more process gases 166″ into the interior of the reaction chamber 102′. One or more static gas injectors 106 may be utilized for introducing the process gases 166″, which may comprise, for example, one or more group V precursors such as arsine, phosphine, ammonia and hydrazine, as well as carrier gases, dopant gases and dilutant gases.

The process of discharging one or more process gases 166″ from the one or more static gas injectors 106 may further include discharging the one or more process gases 166″ in a downward direction (from the perspective of the figures) toward the one or more substrates 122 carried by substrates support structure 104. For example, the process gases 166″ may be discharged in a downward direction oriented at least substantially parallel to the axis of rotation 128 toward the one or more substrates 122 carried by substrates support structure 104. Process gas may be introduced into the antechamber 178 through the gas inlet ports 176. The process gas may then pass from the antechamber 178 into the interior of the reaction chamber 102′ through the gas permeable base plate 180, thereby producing gas streams 166″ that are directed in a downward direction (from the perspective of the figures) toward the substrates 122. Embodiments of methods of the invention may also include protecting the one or more static gas injectors 106 from unwanted deposits by utilizing gas streams 166″ that are oriented in a downward direction (e.g., substantially parallel to the axis of rotation 128) to shield the one or more static gas injectors 106 from unwanted deposits.

The process of discharging one or more process gases 166 from the mobile gas injector 108 and/or the one or more static gas injectors 106 may be utilized for forming a desired material upon the one or more substrates 122 carried by the substrate support structure 104.

In greater detail, the one or more substrates 122 may be heated to a deposition temperature utilizing, for example, one or more heating elements. The heating elements may comprise, for example resistive heating elements, lamp based heating elements, inductive heating elements, radio frequency heating elements, etc., (not shown) for raising the temperature of the substrates 122 to a desirable temperature for deposition. Process gases 166 may be discharged from the mobile gas injector 108 and/or the one or more static gas injectors 106 while rotating one or more of the mobile gas injector 108 and the substrate support structure 104 about the axis of rotation 128, such that one or more materials are deposited upon the heated substrates 122.

As a non-limiting example, the one or more substrates 122 may comprise sapphire, and may be heated to a temperature of greater than approximately 900° C. while rotating the substrate support structure 104 about the axis of rotation 128 at a rotational speed of about one hundred revolutions per minute (100 rpm) or less. The one or more static gas injectors 106 may be utilized for the introduction of a gas stream 166″ comprising ammonia (NH₃) into the interior of the reaction chamber 102′ in a downward direction (from the perspective of the figures). Meanwhile, the one or more gas outlet ports 140 associated with the mobile gas injector 108 may be utilized for discharging one or more radial gas streams 166′ comprising trimethylgallium in a direction oriented at an angle (e.g., at least substantially perpendicular) to the axis of rotation 128. The ammonia and trimethylgallium are substantially prevented from premature mixing due to the separation distance d₃ between the gas outlet ports 140 of the mobile gas injector 108 and the gas outlet ports 142 of the one or more static gas injectors 106, and due to presence of the deflector plates 170′, 170″. Ammonia and trimethylgallium may interact with one another over and proximate to (e.g., at least substantially adjacent) the one or more heated substrates 122, which may result in the formation of a gallium nitride semiconductor material upon the substrates 122.

Upon formation of a desired material to a desired thickness, the flow of the process gases discharged from the mobile gas injector 108 and the one or more static gas injectors 106 may be halted.

Embodiments of methods of the invention may continue by repositioning the one or more gas outlet ports 140 associated with the mobile gas injector 108 by decreasing the first separation distance d₁ between the one or more gas outlet ports 140 of the mobile gas injector 108 and the gas outlet ports 142 of the one or more static gas injectors 106, and increasing the second separation distance d₂ between the one or more gas outlet ports 140 of the mobile gas injector 108 and the substrate support structure 104. Such a repositioning of the one or more gas outlet ports 140 associated with the mobile gas injector 108 may place the gas outlet ports 140 proximate to the one or more static gas injectors 106, and provide a substantial separation between the base 168 of the mobile gas injector 108 and the substrate support structure 104. The substantial separation between the base 168 of the mobile gas injector 108 and the substrate support structure 104 may be sufficient for the introduction of the mechanism 144, as previously discussed, for the retrieval of substrates 122 with desired material or materials deposited thereon.

Additional non-limiting example embodiments are described below:

### Embodiment 1

A system for a gas treatment of at least one substrate, comprising: a reaction chamber; at least one substrate support structure configured to hold at least one substrate disposed within the reaction chamber, the at least one substrate support structure being rotatable about an axis of rotation of the at least one substrate support structure; at least one static gas injector disposed over the substrate support structure within the reaction chamber; and at least one mobile gas injector disposed over the substrate support structure, the at least one mobile gas injector being movable toward and away from the at least one substrate support structure, the mobile gas injector comprising: a drive for moving the at least one mobile gas injector toward and away from the at least one substrate support structure; and one or more gas outlet ports for discharging one or more process gases from the at least one mobile gas injector.

### Embodiment 2

The system of Embodiment 1, wherein the one or more gas outlet ports of the at least one mobile gas injector are disposed proximate to a base of the at least one mobile gas injector and configured to discharge the one or more process gases in at least one direction oriented at an angle greater than zero to the rotational axis of the at least one substrate support structure.

### Embodiment 3

The system of Embodiment 2, wherein the one or more radial gas streams are discharged over the at least one substrate in a perpendicular direction to the axis of rotation.

### Embodiment 4

The system of Embodiment 2 or Embodiment 3, wherein the at least one mobile gas injector further includes at least one deflector plate configured to direct the one or more process gases in the at least one direction, the at least one deflector plate disposed on a side of the one or more gas outlet ports of the at least one mobile gas injector remote from the at least one substrate support structure.

### Embodiment 5

The system of any one of Embodiments 1 through 4, wherein the at least one mobile gas injector further comprises a rotation drive configured to drive rotation of the at least one mobile gas injector around the axis of rotation.

### Embodiment 6

The system of any one of Embodiments 1 through 5, wherein the drive for moving the at least one mobile gas injector toward and away from the at least one substrate support structure controls a first separation distance between the one or more gas outlet ports of the at least one mobile gas injector and the at least one static gas injector.

### Embodiment 7

The system of any one of Embodiments 1 through 6, wherein the drive for moving the at least one mobile gas injector toward and away from the at least one substrate support structure controls a second separation distance between the one or more gas outlet ports of the at least one mobile gas injector and the at least one substrate support structure.

### Embodiment 8

The system of any one of Embodiments 1 through 7, wherein the at least one static gas injector includes an aperture extending through the at least one static gas injector, the aperture having a central axis coincident with the axis of rotation.

### Embodiment 9

The system of Embodiment 8, wherein the aperture is sized and configured to receive the mobile gas injector, the central axis of the aperture being coincident with the central axis of the mobile gas injector.

### Embodiment 10

The system of any one of Embodiments 1 through 9, wherein the at least one static gas injector further comprises: at least one gas feedline in fluid connection with an antechamber; a porous gas permeable base plate disposed at a base of the antechamber; and a plurality of gas outlet ports in fluid communication with the antechamber through the porous gas permeable base plate, the plurality of gas outlet ports configured to discharge at least one process gas toward the at least one substrate.

### Embodiment 11

A gas treatment system, comprising: at least one substrate support structure configured to hold at least one substrate within a reaction chamber; a first gas injector separated from the at least one substrate support structure; and a second gas injector comprising at least one gas outlet port disposed between the first gas injector and the at least one substrate support structure, the second gas injector being movable between a first position and a second position within the reaction chamber, the at least one gas outlet port of the second gas injector located closer to the at least one substrate support structure when the second gas injector is in the second position relative to when the second gas injector is in the first position.

### Embodiment 12

The gas treatment system of Embodiment 11, wherein the first gas injector is configured to discharge at least a first process gas, and wherein the second gas injector is configured to discharge at least a second process gas, the second process gas differing from the first process gas.

### Embodiment 13

A method for the gas treatment of at least one substrate within a reaction chamber, comprising: positioning at least one gas outlet port of at least one mobile gas injector at a first location within the reaction chamber, comprising: decreasing a first separation distance between the at least one gas outlet port of the at least one mobile gas injector and at least one static gas injector; and increasing a second separation distance between the at least one gas outlet port of the at least one mobile gas injector and a substrate support structure within the reaction chamber; loading at least one substrate upon the substrate support structure; moving the at least one gas outlet port of the at least one mobile gas injector from the first location to a second location within the reaction chamber, comprising: increasing the first separation distance between the at least one gas outlet port of the at least one mobile gas injector and the at least one static gas injector; and decreasing the second separation distance between the at least one gas outlets port of the at least one mobile gas injector and the substrate support structure; and discharging at least one process gas from the at least one mobile gas injector and at least another, different process gas from the at least one static gas injector.

### Embodiment 14

The method of Embodiment 13, further comprising: returning the at least one gas outlet port of the at least one mobile gas injector from the second location to the first location within the reaction chamber, comprising: decreasing the first separation distance between the at least one gas outlet port of the at least one mobile gas injector and the at least one static gas injector; and increasing the second separation distance between the at least one gas outlet port of the at least one mobile gas injector and the substrate support structure; and unloading the at least one substrate from the substrate support structure.

### Embodiment 15

The method of Embodiment 13 or Embodiment 14, wherein discharging the at least one process gas from the at least one mobile gas injector further comprises discharging the at least one process gas from the at least one mobile gas injector in a direction oriented perpendicular to an axis of rotation of the substrate support structure.

### Embodiment 16

The method of any one of Embodiments 13 through 15, wherein discharging the at least one process gas from the at least one mobile gas injector further comprising directing the at least one process gas discharged from the at least one mobile gas injector utilizing a deflector plate.

### Embodiment 17

The method of any one of Embodiments 13 through 16, further comprising at least one of rotating the at least one mobile gas injector about an axis of rotation and rotating the substrate support structure about an axis of rotation while discharging the at least one process gas from the at least one mobile gas injector and the at least another, different process gas from the at least one static gas injector.

### Embodiment 18

The method of any one of Embodiments 13 through 17, wherein moving the at least one gas outlet port of the at least one mobile gas injector from the first location to the second location within the reaction chamber further comprises moving the at least one mobile gas injector through an aperture extending through the at least one static gas injector.

### Embodiment 19

The method of any one of Embodiments 13 through 18, wherein discharging the at least another, different process gas from the at least one static gas injector further comprises discharging of the at least another, different process gas from the at least one static gas injector through a plurality of gas outlet ports in fluid communication with an antechamber through a porous gas permeable base plate.

### Embodiment 20

The method of any one of Embodiments 13 through 19, wherein discharging the at least another, different process gas from the at least one static gas injector further comprises discharging the at least another, different process gas in a direction oriented at least substantially parallel to an axis of rotation of the substrate support structure.

### Embodiment 21

The method of any one of Embodiments 13 through 20, wherein moving the at least one gas outlet port of the at least one mobile gas injector from the first location to the second location with the reaction chamber further comprises: actuating a drive; and altering a volume of an antechamber connected to the drive using a flexible bellows.

### Embodiment 22

The method of any one of Embodiments 13 through 21, further comprising forming at least one material upon the at least one substrate within the reaction chamber using the at least one process gas discharged from the at least one mobile gas injector and the at least another, different process gas discharged from the at least one static gas injector.

The embodiments of the invention described above are merely examples of embodiments of the invention and do not limit the scope of the invention, which is defined by the appended claims and their legal equivalents. Any equivalent embodiments are within the scope of this invention. Indeed, various modifications of the example embodiments of the invention shown and described herein, such as alternate useful combinations of the elements described herein, also fall within the scope of the appended claims. Headings and legends are used herein for clarity and convenience only.

1. A system for a gas treatment of at least one substrate, comprising:
a reaction chamber;
at least one substrate support structure configured to hold at least one substrate disposed within the reaction chamber, the at least one substrate support structure being rotatable about an axis of rotation of the at least one substrate support structure;
at least one static gas injector disposed over the substrate support structure within the reaction chamber; and
at least one mobile gas injector disposed over the substrate support structure, the at least one mobile gas injector being movable toward and away from the at least one substrate support structure, the mobile gas injector comprising:
a drive for moving the at least one mobile gas injector toward and away from the at least one substrate support structure; and
one or more gas outlet ports for discharging one or more process gases from the at least one mobile gas injector.

2. The system of claim 1, wherein the one or more gas outlet ports of the at least one mobile gas injector are disposed proximate to a base of the at least one mobile gas injector and configured to discharge the one or more process gases in at least one direction oriented at an angle greater than zero to the rotational axis of the at least one substrate support structure.

3. The system of claim 2, wherein the one or more radial gas streams are discharged over the at least one substrate in a perpendicular direction to the axis of rotation.

4. The system of claim 2, wherein the at least one mobile gas injector further includes at least one deflector plate configured to direct the one or more process gases in the at least one direction oriented at an angle greater than zero to the rotational axis of the at least one substrate support structure, the at least one deflector plate disposed on a side of the one or more gas outlet ports of the at least one mobile gas injector remote from the at least one substrate support structure.

5. The system of claim 1, wherein the at least one mobile gas injector further comprises a rotation drive configured to drive rotation of the at least one mobile gas injector around the axis of rotation.

6. The system of claim 1, wherein the drive for moving the at least one mobile gas injector toward and away from the at least one substrate support structure controls a first separation distance between the one or more gas out let outlet ports of the at least one mobile gas injector and the at least one static gas injector.

7. The system of claim 1, wherein the drive for moving the at least one mobile gas injector toward and away from the at least one substrate support structure controls a second separation distance between the one or more gas out let outlet ports of the at least one mobile gas injector and the at least one substrate support structure.

8. The system of claim 1, wherein the at least one static gas injector includes an aperture extending through the at least one static gas injector, the aperture having a central axis coincident with the axis of rotation.

9. The system of claim 8, wherein the aperture is sized and configured to receive the mobile gas injector, the central axis of the aperture being coincident with the central axis of the mobile gas injector.

10. The system of claim 1, wherein the at least one static gas injector further comprises:
at least one gas feedline in fluid connection with an antechamber;
a porous gas permeable base plate disposed at a base of the antechamber; and
a plurality of gas outlet ports in fluid communication with the antechamber through the porous gas permeable base plate, the plurality of gas outlet ports configured to discharge at least one process gas toward the at least one substrate.

11. A gas treatment system, comprising:
at least one substrate support structure configured to hold at least one substrate within a reaction chamber;
a first gas injector separated from the at least one substrate support structure; and
a second gas injector comprising at least one gas outlet port disposed between the first gas injector and the at least one substrate support structure, the second gas injector being movable between a first position and a second position within the reaction chamber, the at least one gas outlet port of the second gas injector located closer to the at least one substrate support structure when the second gas injector is in the second position relative to when the second gas injector is in the first position.

12. The gas treatment system of claim 11, wherein the first gas injector is configured to discharge at least a first process gas, and wherein the second gas injector is configured to discharge at least a second process gas, the second process gas differing from the first process gas.

13. A method for the gas treatment of at least one substrate within a reaction chamber, comprising:
positioning at least one gas outlet port of at least one mobile gas injector at a first location within the reaction chamber, comprising:
decreasing a first separation distance between the at least one gas outlet port of the at least one mobile gas injector and at least one static gas injector; and
increasing a second separation distance between the at least one gas outlet port of the at least one mobile gas injector and a substrate support structure within the reaction chamber;
loading at least one substrate upon the substrate support structure;
moving the at least one gas outlet port of the at least one mobile gas injector from the first location to a second location within the reaction chamber, comprising:
increasing the first separation distance between the at least one gas outlet port of the at least one mobile gas injector and the at least one static gas injector; and
decreasing the second separation distance between the at least one gas outlets port of the at least one mobile gas injector and the substrate support structure; and
discharging at least one process gas from the at least one mobile gas injector and at least another, different process gas from the at least one static gas injector.

14. The method of claim 13, further comprising:
returning the at least one gas outlet port of the at least one mobile gas injector from the second location to the first location within the reaction chamber, comprising:
decreasing the first separation distance between the at least one gas outlet port of the at least one mobile gas injector and the at least one static gas injector; and
increasing the second separation distance between the at least one gas outlet port of the at least one mobile gas injector and the substrate support structure; and
unloading the at least one substrate from the substrate support structure.

15. The method of claim 13, wherein discharging the at least one process gas from the at least one mobile gas injector further comprises discharging the at least one process gas from the at least one mobile gas injector in a direction oriented perpendicular to an axis of rotation of the substrate support structure.

16. The method of claim 13, wherein discharging the at least one process gas from the at least one mobile gas injector further comprising directing the at least one process gas discharged from the at least one mobile gas injector utilizing a deflector plate.

17. The method of claim 13, further comprising at least one of rotating the at least one mobile gas injector about an axis of rotation and rotating the substrate support structure about an axis of rotation while discharging the at least one process gas from the at least one mobile gas injector and the at least another, different process gas from the at least one static gas injector.

18. The method of claim 13, wherein moving the at least one gas outlet port of the at least one mobile gas injector from the first location to the second location within the reaction chamber further comprises moving the at least one mobile gas injector through an aperture extending through the at least one static gas injector.

19. The method of claim 13, wherein discharging the at least another, different process gas from the at least one static gas injector further comprises discharging of the at least another, different process gas from the at least one static gas injector through a plurality of gas outlet ports in fluid communication with an antechamber through a porous gas permeable base plate.

20. The method of claim 13, wherein discharging the at least another, different process gas from the at least one static gas injector further comprises discharging the at least another, different process gas in a direction oriented at least substantially parallel to an axis of rotation of the substrate support structure.

21. The method of claim 13, wherein moving the at least one gas outlet port of the at least one mobile gas injector from the first location to the second location with the reaction chamber further comprises:
actuating a drive; and
altering a volume of an antechamber connected to the drive using a flexible bellows.

22. The method of claim 13, further comprising forming at least one material upon the at least one substrate within the reaction chamber using the at least one process gas discharged from the at least one mobile gas injector and the at least another, different process gas discharged from the at least one static gas injector.
